(19) United States
(12) Patent Application Publication
(10) Pub. No.: US 2006/0087331 A1
(43) Pub. Date: Apr. 27, 2006

(54) System and method for a multisite, integrated, combination probe card and spider card

(76) Inventors: Michael Edward Young, Dallas, TX (US); Mark Harold Higginbottom, Plano, TX (US)

Correspondence Address: TEXAS INSTRUMENTS INCORPORATED, P O BOX 655474, M/S 3999, DALLAS, TX, 75265, US

(21) Appl. No.: 10/971,422

(22) Filed: Oct. 22, 2004

(51) Int. Cl. G01R 31/02

(52) U.S. Cl. 324/754

(57) ABSTRACT

System and method for a multisite, integrated combination probe card and spider card. A preferred embodiment comprises a series of signal pins configured to mate with test equipment, a socket region coupled to a plurality of integrated circuits, and an open electrical connections block coupled to the series of signal pins and the socket region. If the combination card is to be used as a probe card, then the open electrical connections block is configured to decouple the series of electrical pins from the socket region and a hole is made in the socket region to hold a probe header. If the combination card is to be used as a spider card, then the open electrical connections block is configured to couple the series of electrical pins with the socket region and sockets for holding packaged integrated circuits are added to the socket region.

### TECHNICAL FIELD

The present invention relates generally to a system and method integrated circuit testing, and more particularly to a system and method for a multisite, integrated, combination probe card and spider card.

### BACKGROUND

The manufacture (including fabricating and packaging) of integrated circuits can require that the integrated circuits be tested to ensure that the integrated circuits meet the manufacturer's and/or the customer's specifications. The testing of the integrated circuits can take place either after the fabrication of the integrated circuits or after the integrated circuits have been packaged. The testing of integrated circuits post fabrication can involve the testing of integrated circuits in an uncut from the wafer form and can involve the use of probe pins housed in a probe card for making electrical contact with input/output pads of an integrated circuit.

The use of probe cards can result in difficult testing since the targets of the probe pins, the input/output pads of the integrated circuits, can be extremely small and may be quite delicate. It is possible for a misaligned probe pin to miss an input/output pad, pierce an input/output pad in its entirety and damage underlying circuitry, miss making electrical contact with an input/output pad, and so forth. Therefore, it can be difficult to perform testing on an unpackaged integrated circuit. Not only is performing the test difficult, it can be even more difficult to debug the testing hardware and software, since there is a large degree of uncertainty to the use of the probe pins. Due to uncertainties, such as those discussed above, it can be difficult to determine what exactly is faulty: the test equipment, the probe card, the integrated circuits, and so forth.

A prior art technique for debugging test hardware and software for use in testing unpackaged integrated circuits can make use of an adapter board (referred to as a spider card) to facilitate the testing of packaged integrated circuits. The spider card can replace the probe card and can hold one or more packaged integrated circuits. The use of packaged integrated circuits can help eliminate many of the uncertainties involved in the use of probe pins, such as misaligned pins, spotty electrical contacts, and so forth. The prior art technique can make use of packaged integrated circuits that are known to be good in the test. For example, if the test still fails with the use of the spider card and the known good packaged integrated circuits, then it is known that a fault lies within the test equipment. If the test passes, then it is known that a fault lies within the probe card.

One disadvantage of the prior art is that the use of a probe card and a spider card requires that two separate designs be created. This incurs additional designing and debugging time and money. Furthermore, in most cases, the production run for a probe card and a spider card will tend to be small. Therefore, the production of the probe cards and the spider cards can be expensive. The use of a single combination card can reduce the overall cost by eliminating one source of non-recurring production costs.

A second disadvantage of the prior art is that in many instances, the design of the probe card will be different from the design of the spider card. Therefore, there is a possibility that the probe card and the spider card will behave differently. This can lead to unexpected results that can lead to additional time and money spent in debugging and design.

### SUMMARY OF THE INVENTION

These and other problems are generally solved or circumvented, and technical advantages are generally achieved, by preferred embodiments of the present invention which provides a system and a method for a multisite, integrated, combination probe card and spider card.

In accordance with a preferred embodiment of the present invention, a combination card comprising a series of signal pins, a socket region coupled to a plurality of integrated circuits, and an open electrical connections block coupled to the series of signal pins and the socket region is provided. Wherein the series of signal pins is configured to mate with a test equipment and to pass electrical signals in and out of the combination card. Wherein the socket region is configured to make electrical contact with each of the plurality of integrated circuits. Wherein the open electrical connections block is configured to electrically couple or decouple the series of electrical pins from the socket region based upon a use of the combination card.

In accordance with another preferred embodiment of the present invention, a test system comprising a test equipment being configured to execute a series of programmed tests on a plurality of integrated circuits under test and to record data produced by the programmed tests and an adapter coupled to the test equipment and the plurality of integrated circuit under test is provided. Wherein the adapter being configured to permit an exchange of electrical signals between the test equipment and the plurality of integrated circuits under test, wherein the adapter comprises a combination card that can be used as either a probe card or a spider card.

In accordance with another preferred embodiment of the present invention, a method for creating an adapter for a test system is provided. The method comprises designing an adapter that can be used as a probe card or a spider card, testing the adapter, producing the adapter, and converting the adapter based upon the use of the adapter.

An advantage of a preferred embodiment of the present invention is that a combination probe card and spider card can be designed and debugged at one time, thereby reducing the chance of unexpected behavior due to having two different designs that could complicate debugging.

A further advantage of a preferred embodiment of the present invention is that since there is a single design for the combination probe card and spider card, the production of the combination card incurs only a single non-recurring cost, which can reduce the overall cost of the test system. Furthermore, less documentation is needed since there is only a single design, thereby reducing time and money spent in producing documents.

Yet another advantage of a preferred embodiment of the present invention is that multiple uncut from the wafer integrated circuits and packaged integrated circuits can be simultaneously tested. This is an advantage since both the probe card and the spider card made from the combination probe card and spider card can test the same number of integrated circuits, yet eliminating an additional source of testing uncertainty that may arise when the probe card and the spider card tests a different number of integrated circuits.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1a and 1b are diagrams of test systems for testing integrated circuits, wherein the integrated circuits are in an uncut form with the capability of automated testing and a packaged form without the intent of automated testing;

FIGS. 2a and 2b are diagrams of test systems using a combination card that is capable of being used as either a probe card or a spider card, according to a preferred embodiment of the present invention;

FIGS. 3a and 3b are diagrams of a combination card prior to being configured for operation as either a probe card or a spider card, according to a preferred embodiment of the present invention;

FIGS. 4a and 4b are diagrams of combination cards as configured for operation as a probe card and a spider card, according to a preferred embodiment of the present invention; and

FIG. 5 is a flow diagram of events involved in the design, test, build, and use of a combination card, according to a preferred embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely a combination probe card and spider card for use in testing integrated circuits, either in uncut from the wafer form or in packaged form. The invention may also be applied, however, to other testing situations wherein there is a desire to produce a test board that can be used for several different test scenarios, resulting in an overall reduction in testing costs.

With reference now to FIGS. 1a and 1b, there are shown diagrams illustrating test systems for testing integrated circuits in both an uncut form and a packaged form. The diagram shown in FIG. 1a illustrates a test system 100 that can be used to test integrated circuits that are in an uncut from the wafer state, wherein the test system 100 has the capability of automated testing. The test system 100 comprises test equipment 105, which may include power supplies, signal generators, logic analyzers, memory devices, storage devices, data capture equipment, data processing equipment, display devices, human interface equipment, and so forth. The test system 100 further comprises a probe card 120 that can be coupled to the test equipment 105 via a prober interface card (PIB) 110 and a pogo pin tower 115. The PIB 110 can serve as a connection interface between the test equipment 105 and the pogo pin tower 115, which can be used as a way to electrically couple the probe card 120 to the PIB 110. The probe card 120 can permit the testing of integrated circuit(s) on a wafer 125 without having to cut the integrated circuits from the wafer 125 and mounting them in packaging. The probe card 120 can have electrically conductive probes or fingers (not shown) that can be lowered onto an integrated circuit. The probes can then make contact with signal pads on the integrated circuit and can then permit the integrated circuit to be powered and signals can be input and output from the integrated circuit.

The diagram shown in FIG. 1b illustrates a test system 150 that can be used to test integrated circuits that are in a packaged state, wherein there is no intent or capability to perform automated testing. An integrated circuit that has been packaged may be thought of as being in a ready for sale, distribution, or use state. The test system 150 comprises test equipment 105 and a spider card 155. As in the test system 100 (FIG. 1a), the spider card 155 is coupled to the test equipment 105 by the PIB 110 and the pogo pin tower 115. The spider card 155 permits the mounting of packaged integrated circuits and permits them to be powered and signals can be input and output from the integrated circuit. A typical spider card 155 can contain an integrated circuit socket (not shown) that can hold a packaged integrated circuit.

The probe card 120 can permit the automated testing of integrated circuits in an uncut form, while the spider card 155 can be used to debug the test system. The probe card 120 can be used as an adapter to permit the testing of various forms of integrated circuits without needing to design a test system for each different form. When a different integrated circuit is to be tested, only a redesign of the probe card 120 is needed, not a redesign of the test system.

The spider card 155, on the other hand, can be used to verify the proper operation of the test system. If integrated circuits are coming out of the test system being marked as faulty, there may be several reasons why the integrated circuits are failing the tests: the integrated circuits are faulty, the test system hardware is faulty, or the test system software is faulty. The spider card 155 can permit the use of the test system with packaged integrated circuits that are known to be good. If the test system still reports faulty integrated circuits, then a fault is known to exist in the test system itself. If the test system reports good integrated circuits, then a fault is known to exist in the uncut integrated circuits. Essentially, the use of the spider card 155 can help to eliminate uncertainty in the test system and to help simplify testing.

However, the probe card 120 and the spider card 155 have to be separately designed for each integrated circuit being tested. The design, test, and build costs involved with each card being created separately can be a significant proportion of an overall testing cost due to the low number of probe cards and spider cards built. Therefore, design, testing, and building costs can be reduced if a single combination card can be designed that can be used for either the probe card 120 or the spider card 155.

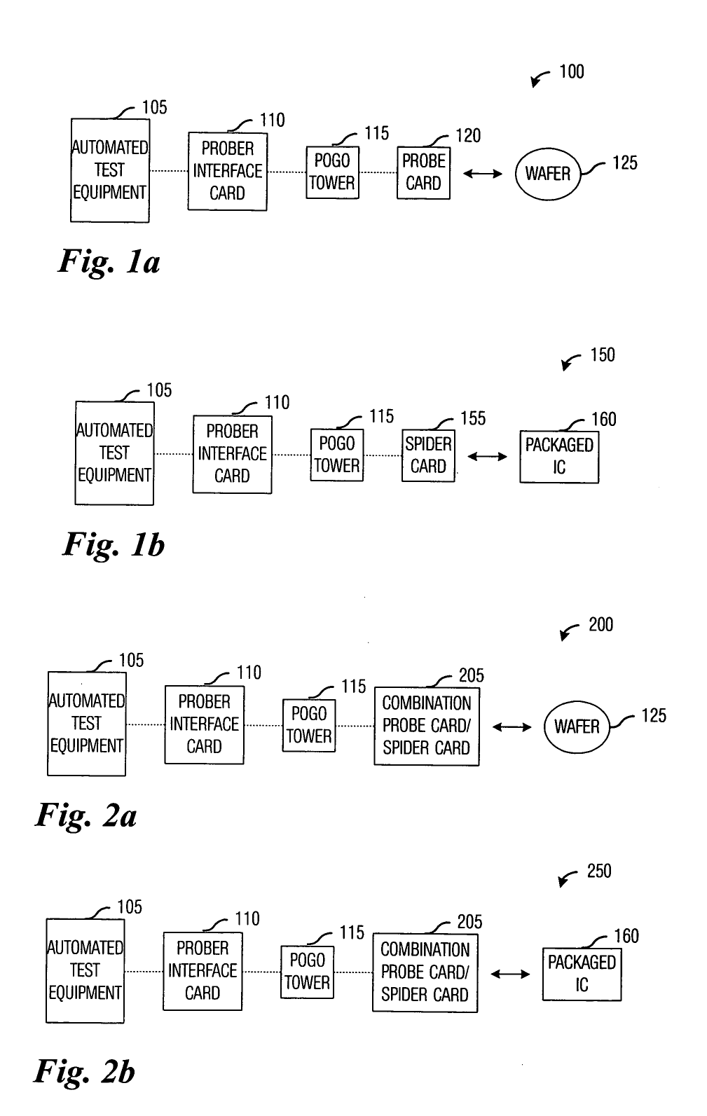

With reference now to FIGS. 2a and 2b, there are shown diagrams illustrating test systems using a combination card that is capable of being used as either a probe card or a spider card, according to a preferred embodiment of the present invention. The diagram shown in FIG. 2a illustrates a test system 200 that makes use of a combination card 205 configured as a probe card to enable the testing of an integrated circuit that is still a part of a wafer 125. The combination card 205 can serve as an adapter for the wafer 125 and enables testing by the test equipment 105.

The diagram shown in FIG. 2b illustrates a test system 250 that makes use of the combination card 205 configured as a spider card to enable the testing of an integrated circuit after it has been turned into a packaged integrated circuit 160, wherein the testing can be used to test the proper function of the test system 250. The combination card 205, in this case, can serve as an adapter for the packaged integrated circuit 160 to enable testing by the test equipment 105.

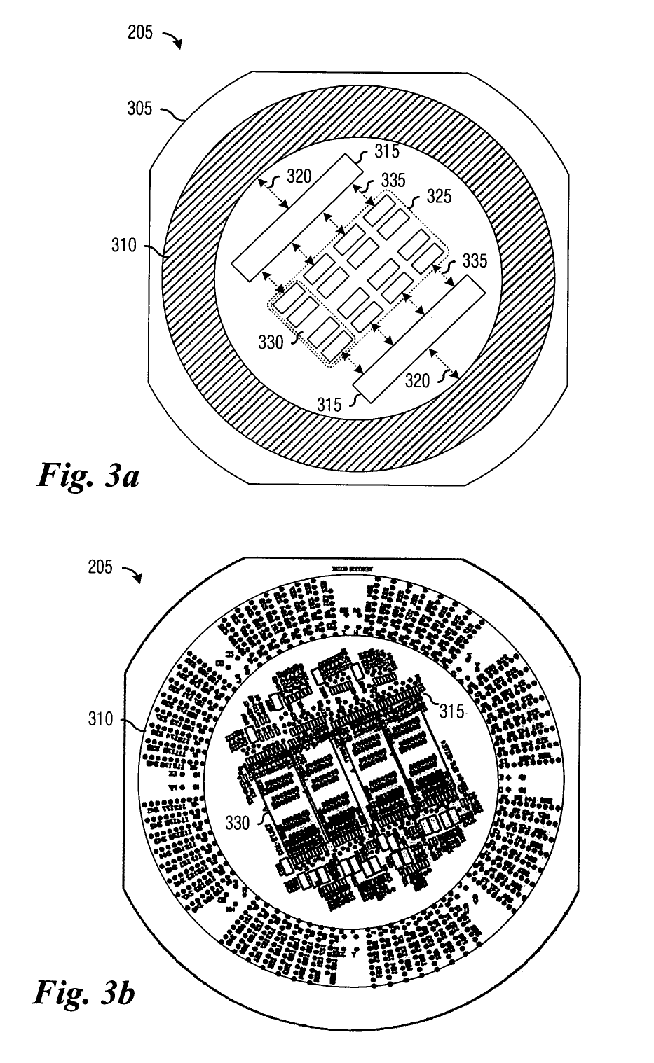

With reference now to FIGS. 3a and 3b, there are shown diagrams illustrating a combination card 205 prior to being configured for operation as either a probe card or a spider card, according to a preferred embodiment of the present invention. The diagram shown in FIG. 3a illustrates a high-level view of the combination card 205, wherein details of the combination card 205 are not shown to maintain simplicity. Components on the combination card 205 with similar functionality or purpose are grouped together to facilitate discussion.

The combination card 205 can be built using a fiberglass board 305 and can contain multiple layers wherein electrically conductive traces can be run. Vias (not shown) can be used to electrically connect traces on different layers. The combination card 205 can be built from boards of other materials that are non-conductive in nature, such as glass, plastic, polymer, FR4 (a fiberglass material), and so forth. The material used to make the combination card 205 does not change the spirit of the present invention.

Enabling electrical connectivity between the combination card 205 and test equipment, such as the test equipment 105 (FIGS. 2a and 2b), can be a series of pins, sometimes referred to as pogo pins, forming an annular region 310 around the perimeter of the combination card 205. It is through the series of pins that the combination card 205 electrically mates with the PIB 110. Another set of pogo pins can then bring the electrical connections back to the test equipment 105. Note that the series of pins may not consume the entire surface area shown as the annular region 310. The placement of pins in the annular region 310 may be dependent upon factors such as the physical requirements of the pins, restrictions on the size and length of electrical traces connecting the pins, and so forth. Furthermore, the placement of the series of pins may not result in the shape of an annular region. However, for ease of design and electrical trace placement, the series of pins will likely to be placed on the outer regions of the combination card 205.

The combination card 205 also comprises a bank of open (conductively open) electrical connections 315 that can be short circuited using zero ohm components or solder bridges that can electrically couple pins in the annular region 310 with electrical traces interior to the annular region 310. The bank of open electrical connections 315 can be used to electrically separate conductive traces and planes from portions of the combination card 205 interior to the annular region 310 from conductive trances and planes in the annular region 310.

Interior to the bank of open electrical connections 315 is a region wherein electrical traces are present to provide connectivity for sockets that can be used to hold packaged integrated circuits. This region can be referred to as a socket region 325. The socket region 325 can contain electrical traces for one or more sockets (a footprint for a socket is shown as region 330). As shown in FIG. 3a, there is sufficient space in the socket region 325 for four sockets, therefore, it can be possible to test up to four packaged integrated circuits at one time in a spider card made from the combination card 205. The bank of open electrical connections 315 can be located in very close proximity to the socket region 325.

A connection 320 can represent electrical traces connecting the series of pins in the annular region 310 to the bank of open electrical connections 315. Note that while the connection 320 is shown as a single connection between the annular region 310 and the bank of open electrical connections 315, it may be representative of a plurality of electrical connections. Furthermore, the connection 320 may also represent electrical components in addition to conductive traces. However, the connection 320 is shown as a single connection solely to maintain simplicity of the diagram. Similarly, a series of connections, such as connection 335 can represent electrical traces (singular and/or plural, as well as electrical components) connecting the bank of open electrical connections 315 to the socket region 325.

An electrical trace may begin at a pogo pin located in the annular region 310 and be routed inwardly, either directly to or through other electrical components to a probe attach point (not shown) located outside of the bank of open electrical connections 315. From the probe attach point, the trace can be routed through an open connection (in the bank of open electrical connections 315) into the socket region 325. The trace can then be terminated at an appropriate test socket pin mount point (not shown).

By default, the bank of open electrical connections 315 is left as open circuits, meaning that an electrical trace leading into the bank of open electrical connections 315 is decoupled from a corresponding electrical trace leading out of the bank of open electrical connections 315 and into the socket region 325. As discussed previously, zero ohm components or solder blocks can be used in the bank of open electrical connections 315 to complete the electrical circuits. According to a preferred embodiment of the present invention, the bank of open electrical connections 315 can be replaced with a bank of fuses. If the bank of open electrical connections 315 were to be replaced with a bank of fuses, then by default, the electrical connections will be closed and an additional operation would be necessary to blow the fuses and disconnect the electrical connections. The fuse banks can contain electrically fusible links or laser trim fuses that can be blown by passing a current of sufficient magnitude through the fuses or by laser cutting.

The combination card 205 is designed for use as either a probe card or a spider card. However, the combination card 205 may require modifications prior to use as either the probe card or the spider card, wherein the modifications may not be reversible. Therefore, once the combination card 205 has been modified for use as either a probe card or a spider card, it can be difficult, if not impossible, to modify the combination card 205 for use as a spider card or a probe card.

According to a preferred embodiment of the present invention, in order to modify the combination card 205 for use as a probe card, the combination card 205 needs to be perforated through the socket region 325 in order to facilitate the mounting of a probe header (not shown). The probe header can be used to hold the electrically conductive probes that make contact with the integrated circuits on the wafer 125. The perforations can be made by drilling out an appropriately sized (and shaped) hole in the combination card 205. After the hole is made, then the probe header can be mounted to the combination card 205. Electrical leads from the probe header can then be connected to probe attach points and pins, which may be located in the annular region 310 and/or to the exterior of the bank of open electrical connections 315 and the socket region 325, preferably on the bottom side of the combination card 205 for the purpose of electrical connectivity to circuitry and components which are electrically connected to pins in the annular region 310.

The drilling of the hole can cause damage to conductive layers inside the combination card 205, potentially causing electrical short circuits in traces running in the socket region 325. The electrical short circuits can result in the combination card 205 not operating properly or even cause damage to the integrated circuits being tested, the combination card 205, or the test equipment 105 due to unexpected currents. According to a preferred embodiment of the present invention, the bank of open electrical connections 315 can be used to electrically decouple the traces in the socket region 325 from all traces and components external to socket region 325 and thereby protect the test equipment 105 and the integrated circuits on the wafer 125 from the potentially damaged traces in the socket region 325 caused by the hole created to place the probe header onto the combination card 205.

According to a preferred embodiment of the present invention, in order to modify the combination card 205 for use as a spider card, one or more sockets can be placed onto the combination card 205. The socket(s) can be fitted in position in the socket region 325, for example, in the region 330. As shown in FIG. 3a, four sockets can be fitted into the socket region 325, permitting the combination card 205, functioning as a spider card, to simultaneously test four packaged integrated circuits. In addition to placing sockets into the socket region 325, electrical jumpers can also be placed in the bank of open electrical connections 315 to create electrical connections between the series of pins in the annular region 310 through the connections 320 and 335 and to the packaged integrated circuits in the sockets. Note that since the placement of the sockets and the electrical jumpers onto the combination card 205 does not result in a physical modification of the combination card 205, it may be possible to convert the combination card 205 into a probe card if the desire exists.

With reference now to FIG. 3b, there is shown a diagram illustrating a top view of a combination card 205, prior to the combination card 205 being populated or being converted for use as either a probe card or a spider card.

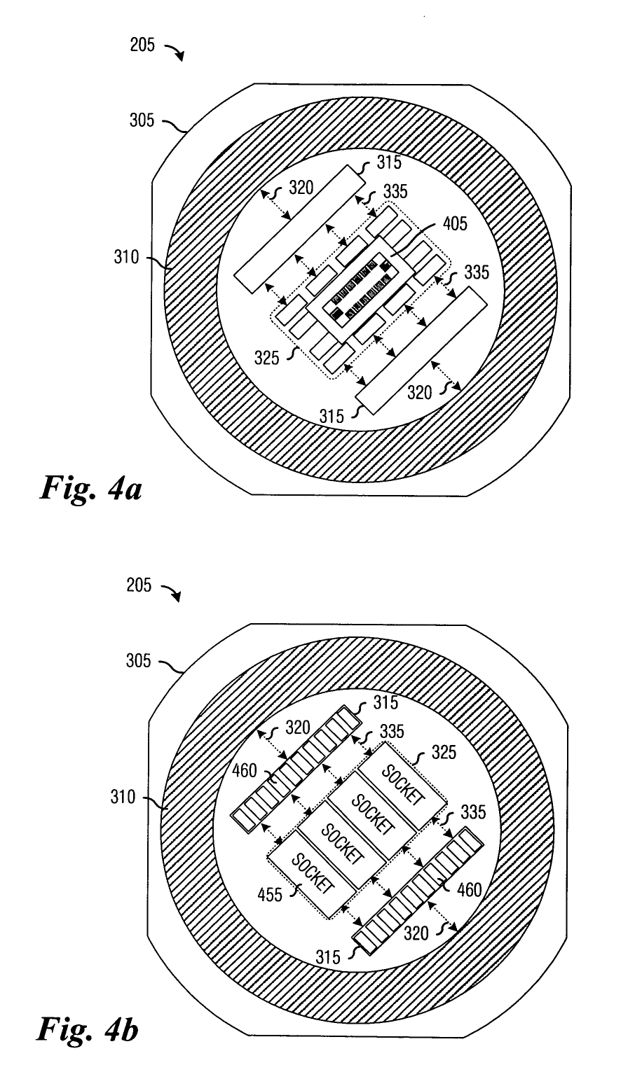

With reference now to FIG. 4a, there is shown a diagram illustrating a combination card 205 after being modified for operation as a probe card, according to a preferred embodiment of the present invention. The diagram shown in FIG. 4a illustrates an exemplary probe card made from the combination card 205. As discussed previously, a probe header 405 is placed onto the combination card 205 after a hole (or a series of holes) has been made in the socket region 325 of the combination card 205. The probe header 405 can be connected electrically to the combination card 205 via a series of electrical connections that can be added after the probe header 405 has been placed onto the combination card 205. For example, the electrical connections can be made via jumpers soldered onto the combination card 205 and the probe header 405.

With reference now to FIG. 4b, there is shown a diagram illustrating a combination card 205 after being modified for operation as a spider card, according to a preferred embodiment of the present invention. The diagram shown in FIG. 4b illustrates an exemplary spider card made from the combination card 205. The spider card can be made from the combination card 205 by placing sockets 455 into position in the socket region 325 of the combination card 205 and by placing zero ohm components 460 (or solder bumps or electrical jumpers) in the bank of open electrical connections 315. The zero ohm components 460 can complete electrical connections created in the combination card 205 in the design process.

As discussed previously, the use of a separately designed probe card and spider card can be an inefficient and expensive approach to the testing of integrated circuits. The probe card and the spider card will need to be separately designed, debugged, and tested. This essentially incurs twice the development cost of a single board. Additionally, with probe card and spider card production numbers being typically very low, the per cost of each card is very high, due mostly to non-recurring production costs. Furthermore, since the probe card and the spider card are designed separately (and often by different designers), the overall layout of the two cards will tend to be different. This can lead to the different placement of components and conductive traces and can result in unexpected behavior when the cards are used. This can further complicate the debugging process.

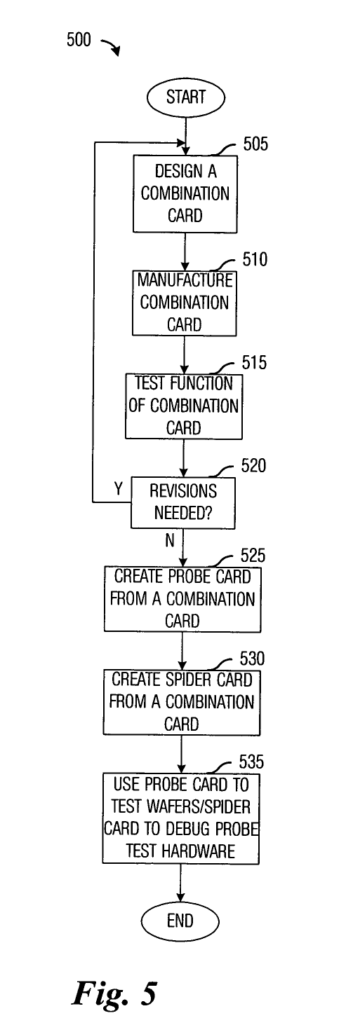

With reference now to FIG. 5, there is shown a diagram illustrating a sequence of events 500 involved in the design, test, build, and use of a combination card, according to a preferred embodiment of the present invention. In the above discussion, some of the difficulties involved in the design, test, and use of separate probe and spider cards were highlighted. Therefore, it may be cost advantageous, both in terms of money and time expended, to design a single card that can be used as either a probe card or a spider card. The sequence of events 500 involved in the design, test, build, and use of a combination card can begin with the design of the combination card 205 (block 505). Since the combination card is a single unit, a single engineer is likely to design such a card, thereby eliminating functional inconsistencies that can be due to different designers designing two different cards with similar intended function. After the combination card 205 is designed, it can be manufactured (block 510). Because there is only a single card to manufacture, only a single non-recurrent production cost is incurred. Furthermore, since the combination card 205 is to be used as both a probe card and a spider card, the number of combination cards 205 that will be manufactured is likely to be twice the number of probe cards or spider cards manufactured. This will further decrease the cost per card.

After a few combination cards 205 have been manufactured, their function can be tested (block 515). If the combination cards 205 operate as intended, the remaining combination cards 205 can be manufactured. If the combination cards 205 do not operate as intended, then revisions to the design of the combination card 205 may be needed (block 520) and the designer will need to make revisions to the design. Once the combination cards 205 have passed functional testing, the combination cards 205 can be converted into probe cards (block 525) and spider cards (block 530) and then used to test integrated circuits in wafer form (using probe cards) or packaged form (using spider cards) (block 535).

Although the present invention and its advantages have been described in detail, it should be understood that various changes, substitutions and alterations can be made herein without departing from the spirit and scope of the invention as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A combination card comprising:
a series of signal pins, the series of signal pins being configured to mate with a test equipment and to pass electrical signals in and out of the combination card;
a socket region coupled to a plurality of integrated circuits, the socket region being configured to make electrical contact with each of the plurality of integrated circuits; and
an open electrical connections block coupled to the series of signal pins and the socket region, the open electrical connections block being configured to electrically couple or decouple the series of electrical pins from the socket region based upon a use of the combination card

2. The combination card of claim 1, wherein the open electrical connections block decouples the series of electrical pins from the socket region when the combination card is used as a probe card.

3. The combination card of claim 2 further comprising a probe header coupled to the series of signal pins, the probe header configured to make electrical contact with signal pads on a surface of a plurality of unpackaged integrated circuits, wherein the probe header is located in a hole made in the socket region of the combination card.

4. The combination card of claim 3, wherein the probe header is coupled to the series of signal pins by a series of jumper wires.

5. The combination card of claim 3, wherein the plurality of unpackaged integrated circuits is located on a semiconductor wafer.

6. The combination card of claim 3, wherein the hole is made after the creation of the combination card.

7. The combination card of claim 1, wherein the open electrical connections block couples the series of electrical pins from the socket region when the combination card is used as a spider card.

8. The combination card of claim 7 further comprising a plurality of sockets coupled to electrical traces in the socket region, each socket configured to retain a packaged integrated circuit and to permit an exchange of electrical signals from the series of signal pins and the packaged integrated circuit.

9. The combination card of claim 8, wherein all sockets in the plurality of sockets are identical.

10. The combination card of claim 7, wherein the open electrical connections block comprises zero ohm components that are soldered into position.

11. The combination card of claim 1, wherein the series of signal pins is arranged in an annular ring around the socket region and the open electrical connections block.

12. The combination card of claim 1, wherein connections in the open electrical connections block are fuses that can be blown electrically or trimmed via a laser.

13. A test system comprising:
test equipment being configured to execute a series of programmed tests on a plurality of integrated circuits under test and to record data produced by the programmed tests; and
an adapter coupled to the test equipment and the plurality of integrated circuits under test, the adapter being configured to permit an exchange of electrical signals between the test equipment and the plurality of integrated circuits under test, wherein the adapter comprises a combination card that can be used as either a probe card or a spider card.

14. The test system of claim 13, wherein the adapter comprises:
a series of signal pins, the series of signal pins configured to mate with the test equipment and to pass electrical signals in and out of the combination card;
a socket region coupled to a plurality of integrated circuits, the socket region configured to make electrical contact with each of the plurality of integrated circuits; and
an open electrical connections block coupled to the series of signal pins and the socket region, the open electrical connections block configured to electrically decouple or decouple the series of electrical pins from the socket region based upon a use of the combination card.

15. The test system of claim 14, wherein the open electrical connections block decouples the series of electrical pins from the socket region when the combination card is used as a probe card.

16. The test system of claim 15 further comprising a probe header coupled to the series of signal pins, the probe header configured to make electrical contact with signal pads on a surface of a plurality of unpackaged integrated circuits, wherein the probe header is located in a hole made in the socket region of the combination card.

17. The test system of claim 14, wherein the open electrical connections block couples the series of electrical pins from the socket region when the combination card is used as a spider card.

18. The test system of claim 17 further comprising a plurality of sockets coupled to electrical traces in the socket region, each socket configured to retain a packaged integrated circuit and to permit an exchange of electrical signals from the series of signal pins and the packaged integrated circuit.

19. The test system of claim 13 further comprising:
a prober interface card coupled between the test equipment and the adapter, the prober interface card to interface the test equipment to the adapter; and
a pin tower coupled between the prober interface card and the adapter, the pin tower to permit the electrical coupling of the adapter to the prober interface card.

20. A method for creating an adapter for a test system, the method comprising:
designing an adapter that can be used as a probe card or a spider card;
testing the adapter;
producing the adapter; and
converting the adapter based upon the use of the adapter.

21. The method of claim 20, wherein if the use of the adapter is as a probe card, then the converting comprises:
making a hole in the adapter;
placing a probe header in the hole;
severing electrical connections between a portion of the adapter wherein the hole is made and electrical connectors to the test system; and
coupling the probe card to the electrical connectors to the test system.

22. The method of claim 21, wherein the severing comprises blowing electrical fuses in a fuse block between the hole and the electrical connectors to the test system.

23. The method of claim 21, wherein the severing comprises removing electrical jumpers in a fuse block between the hole and the electrical connectors to the test system.

24. The method of claim 20, wherein if the use of the adapter is a spider card, then the converting comprises:
adding a plurality of sockets to the adapter; and
coupling the plurality of sockets to electrical connectors to the test system.

25. The method of claim 24, wherein the coupling comprises placing electrical jumpers in a fuse block located between the plurality of sockets and the electrical connectors to the test system.
